(19) United States
(12) Patent Application Publication
(10) Pub. No.: US 2008/0186680 A1
(43) Pub. Date: Aug. 7, 2008

(54) Monolithic Controller for the Generator Unit of a Motor Vehicle

(76) Inventors: Achim Henkel, Reutlingen (DE); Volker Koelsch, Stuttgart (DE); Reinhard Milich, Reutlingen (DE)

Correspondence Address: KENYON & KENYON LLP, ONE BROADWAY, NEW YORK, NY, 10004, US

(21) Appl. No.: 11/587,521

(22) PCT Filed: Feb. 24, 2005
(86) PCT No.: PCT/EP2005/050783

§ 371 Date: Nov. 14, 2007

(30) Foreign Application Priority Data
Apr. 24, 2004 (DE) 10 2004 020 172.2

(51) Int. Cl. H05K 7/20; H02K 11/00

(52) U.S. Cl. 361/719; 310/68 R

(57) ABSTRACT

A monolithic controller for the generator unit of a motor vehicle, which is fixedly connected to a cooling body. The cooling body preferably is a thermally conductive ceramic substrate, which is additionally provided with electrically conductive connections, preferably copper structures. In unpackaged form, the monolithic controller is fixedly connected to the substrate.

### FIELD OF THE INVENTION

The present invention relates to a monolithic controller for the generator unit of a motor vehicle.

### BACKGROUND INFORMATION

An energy supply having redundant generator control for motor vehicles is described in German Patent No. DE 101 50 380 A1. This conventional energy supply, which is provided particularly for the energy supply of vehicle electrical systems, has a battery to which a plurality of load circuits is connected. In addition, it is provided with a generator to charge the battery and a controlling unit to regulate the generator voltage. The controlling unit has a controller, a first switch triggered by the controller to regulate the generator voltage during normal operation, and a second switch, which is able to be triggered by the controller to regulate the generator voltage in case of a malfunction of the first switch.

Controllers for the generator unit of a motor vehicle must be able to satisfy increasingly higher requirements with regard to pulse stability and EMC resistance and also with regard to an electrostatic discharge. The conventional monolithic controllers can satisfy these high requirements only by using external supplemental components. A connection of such supplemental components with the monolithic controller is difficult to accomplish when utilizing the available assembly concepts. Apart from that, the market requirements are not uniform. The requirements regarding the configuration of the controller largely depend on the individual vehicle into which the controller is to be installed. This considerably complicates a large-scale production of controllers.

### SUMMARY

A monolithic controller according to an example embodiment of the present invention may be easily adaptable to the individual customer requirements. If a customer intends to use the monolithic controller in an environment in which the requirements with respect to pulse stability, EMC resistance and electrostatic discharge (ESD stability) are relatively low, then it is possible to supply this customer with the monolithic controller, which in unpackaged form is affixed on the substrate, without supplemental components. This keeps the price of the monolithic controller relatively low. If another customer wants to use the monolithic controller in an environment where the requirements with respect to pulse stability, EMC resistance and/or electrostatic discharge are high, then this other customer may be supplied with the monolithic controller, which in unpackaged form is affixed on the substrate, with one or a plurality of supplemental components that are required to satisfy the mentioned high requirements. One and the same assembly line may be used to produce the two previously mentioned controllers.

The same assembly line may also be utilized to produce monolithic controllers that are fixedly connected to a cooling body, which, for instance, is a solid block made of copper whose dimensions conform to the dimensions of the substrate having the electrically conductive connections.

The modular monolithic controller according to the example embodiment of the present invention also may have the advantage that the individually required supplemental components, which are preferably SMD components, are able to be mounted on the substrate in a simple and cost-effective manner.

Bond pads mounted on the substrate are preferably used for the electrical contacting of an individual SMD component and the monolithic controller or an external component. To avoid external wiring, the electrical contacting of an SMD component with an additional SMD component is implemented via the electrically conductive connections within the substrate. The electrical contacting of an SMD component with the monolithic controller is realized via conductors that are not part of the substrate, i.e., via external wiring. Even the electrical contacting of an SMD component with components that are not mounted on the substrate is implemented via conductors that are not part of the substrate.

The rear side of the monolithic controller is mounted on the substrate, for instance by bonding or soldering. Those regions of the substrate in which the monolithic controller is affixed may be free of electrically conductive connections. The electrical contacting of the monolithic controller with one of the SMD components or other components is implemented via bond pads provided on the front side of the monolithic controller, with the aid of conductors or fine wires extending outside of the substrate.

### BRIEF DESCRIPTION OF THE DRAWINGS

FIG. 1 shows a block diagram to illustrate a first exemplary embodiment of the present invention.

FIG. 2 shows a sketch to illustrate the mechanical configuration of the circuit shown in FIG. 1.

FIG. 3 shows a block diagram to illustrate a second exemplary embodiment of the present invention.

FIG. 4 shows a sketch to illustrate the mechanical configuration of the circuit shown in FIG. 3.

### DETAILED DESCRIPTION OF EXAMPLE EMBODIMENTS

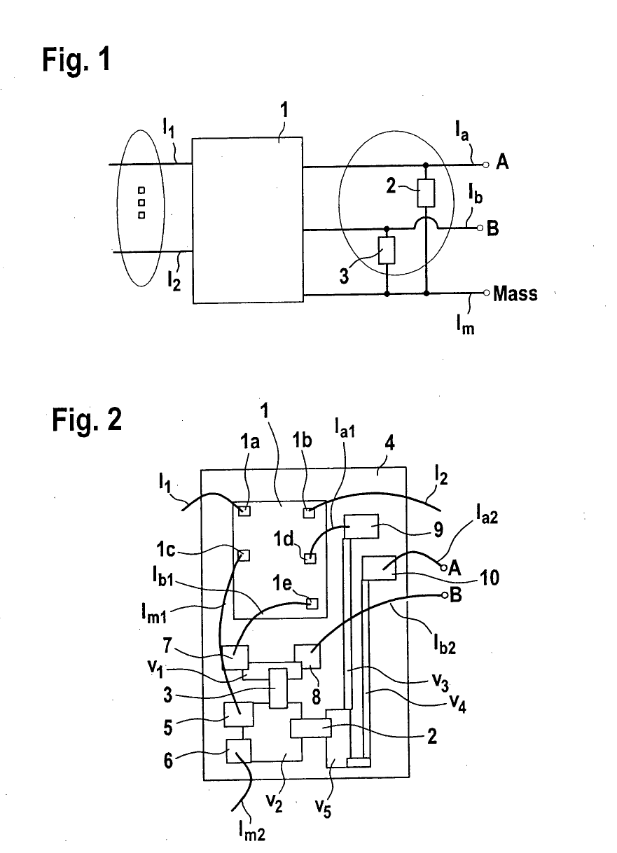

FIG. 1 shows a block diagram to illustrate a first exemplary embodiment of the present invention. According to this exemplary embodiment, a monolithic controller 1 is connected to a generator unit (not shown) via connector leads 1₁, . . . , 1₂. In addition, monolithic controller is connected to a connection point A via a connector lead 1ₐ; to a connection point B via a connector lead 1_{b}; and to ground via a connector lead 1ₘ A first supplemental component 2 is connected between connector lead 1ₐ and connector lead 1ₘ. A second supplemental component 3 is connected between connector lead 1_{b} and connector lead 1ₘ. Monolithic controller 1 encompasses the entire functionality of a controller for a generator unit, i.e., a driver and a free-wheeling diode as well. Monolithic controller 1 is provided in the form of an unpackaged chip, in particular an unpackaged silicon chip.

Supplemental components 2 and 3 are discrete supplemental components, which are disposed outside of monolithic controller 1 and provided so that the entire device has high pulse stability and high EMC resistance and, furthermore, is able to satisfy the high requirements with respect to electrostatic discharge. Such supplemental components are, in particular, capacitors, resistors and diodes, which are interconnected.

Via connecting points A and B, the cable harness of a motor vehicle is connected, which supplies monolithic controller 1 with control signals via connector lead 1ₐ and which receives data signals from monolithic controller 1 via connector lead 1_{b}. These data signals contain information about the instantaneous state of the generator unit or affect the control response.

FIG. 2 shows a sketch to illustrate the mechanical configuration according to the present invention of the circuit shown in FIG. 1. Monolithic controller 1, present in unpackaged form, is mounted on a cooling body 4 via its rear side, for instance by bonding or soldering. This cooling body 4 is a thermally conductive substrate which has electrically conductive connections v₁, v₂, v₃, v₄, v₅. The substrate is made from a ceramic material, for instance, and conductive connections v₁, v₂, v₃, v₄, v₅ are mounted on the ceramic material.

The particular region of cooling body 4 in which monolithic controller 1 is affixed does not have any electrically conductive connections.

The electrical contacting of monolithic controller 1 with the generator unit is implemented via leads 1₁, . . . , 1₂, of which leads 1₁ and 1₂ are illustrated in FIG. 2. One end of lead 1₁ is secured to a bond pad 1a provided on the front side of monolithic controller 1. Lead 1₁ extends outside of cooling body 4 and is not in electrical contact with it. One end of lead 1₂ is secured to bond pad 1b of monolithic controller 1. Lead 1₂ also extends outside of cooling body 4 and is not electrically contacted by it.

In addition, via its bond pad 1c and a lead 1ₘ₁, monolithic controller 1 is connected to a bond pad 5 mounted on cooling body 4. Lead 1ₘ₁ extends outside of cooling body 4. Bond pad 5 is electrically connected to electrically conductive connection v₂, which, in turn, is electrically connected to an additional bond pad 6 affixed on cooling body 4, from which a lead 1ₘ₂ leads to ground. Lead 1ₘ₂ extends outside of cooling body 4.

Electrically conductive connection v₂ is also connected to a terminal of supplemental component 3. The other terminal of this supplemental component 3 is contacted by electrically conductive connection v₁. This, in turn, is electrically connected to additional bond pads 7 and 8, which are mounted on cooling body 4 in each case. A lead 1_{1b} runs between bond pad 7 and bond pad 1e of monolithic controller 1. A lead 1_{b2} extends between bond pad 8 and external connection point B. Leads 1_{b1} and 1_{b2} extend outside of cooling body 4.

Electrically conductive connection v₂ is also connected to a terminal of supplemental component 2. The other terminal of this supplemental component 2 is connected to electrically conductive connection vs. This, in turn, is connected to a bond pad 9 via electrically conductive connection v₃, and to a bond pad 10 via electrically conductive connection v₄. Bond pads 9 and 10 are mounted on cooling body 4. As an alternative to the illustrated exemplary embodiment, connections v₃ and v₄ may be combined into one connection in order to save space. In addition, bond pad 9 is connected to bond pad 1d of monolithic controller 1 via a lead 1ₐ₁, which extends outside of cooling body 4. Furthermore, bond pad 10 is connected to external connection point A via a lead 1ₐ₂, which extends outside of cooling body 4.

Supplemental components 2 and 3 shown in FIG. 2 are each realized in the form of an SMD component. Electrically conductive connections v₁, v₂ and v₅ on which the SMD components are affixed are receiving elements for SMD components. These receiving elements have a larger surface than required to accommodate SMD components 2 and 3 illustrated in FIG. 2. This has the advantage that, if other requirements exist with respect to the pulse stability, EMC resistance and ESD response, components other than components 2 and 3 may be used, whose dimensions differ from those of components 2 and 3.

Consequently, according to the system shown in FIG. 2, monolithic controller 1 as well as supplemental components 2 and 3 are affixed on the cooling body. This is a thermally conductive substrate, which is provided with electrically conductive connections v₁, v₂, v₃, v₄, v₅, and which has copper structures or electrically conductive paste printing. These electrically conductive connections are contacted by bond pads 5, 6, 7, 8, 9, 10 affixed on substrate 4. The substrate is a ceramic substrate, for instance. Supplemental components 2 and 3 are each disposed between two of the electrically conductive connections. This achieves an electrical interconnection that corresponds to the electrical interconnection illustrated in FIG. 1.

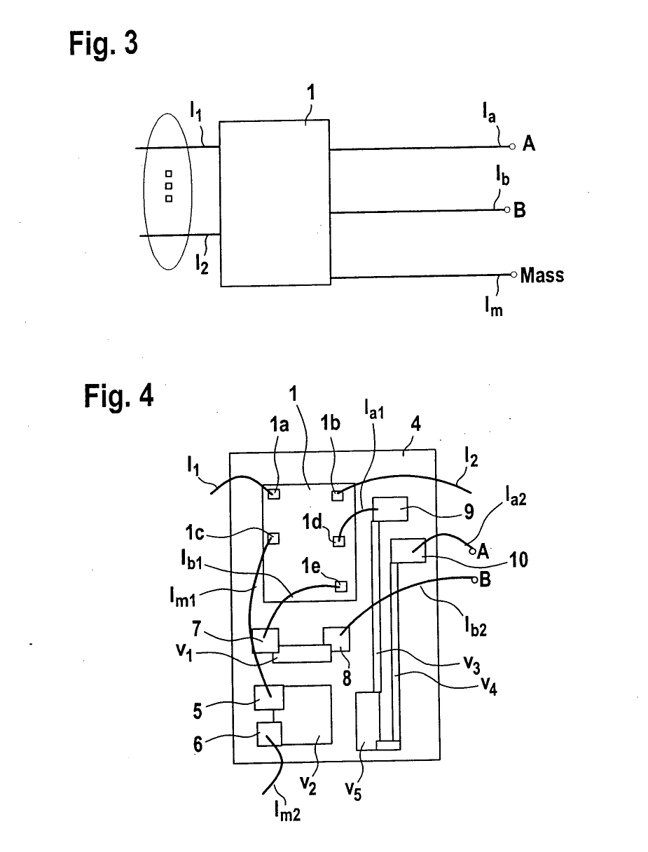

FIG. 3 shows a block diagram to illustrate a second exemplary embodiment of the present invention. The requirements regarding pulse stability, EMC resistance and ESD response for the controller shown in FIG. 3 are lower than those for the controller shown in FIG. 1. In the exemplary embodiment shown in FIG. 3, no additional circuit elements are therefore required between monolithic controller 1 and terminals A, B and ground. Like in the exemplary embodiment shown in FIG. 1, monolithic controller 1 is connected to the generator unit via lines 1₁, . . . , 1₂.

FIG. 4 shows a sketch to illustrate the mechanical configuration of the circuit shown in FIG. 3. The configuration according to FIG. 4 largely conforms to the configuration according to FIG. 2. It differs from the configuration shown in FIG. 2 merely by the missing supplemental components 2 and 3. As a result, in the exemplary embodiment shown in FIG. 4 there is no electrical contact between conductive connections v₁ and v₂ and also no electrical contact between conductive connections v₂ and v₅.

According to FIG. 4, bond pad 1e of monolithic controller 1 is electrically connected to external connection point B via lead 1_{b1}, bond pad 7, electrically conductive connection v₁, bond pad 8 and lead 1_{b2}. This connection corresponds to connection 1_{b} in FIG. 3.

In addition, according to FIG. 4, bond pad 1c of monolithic controller 1 is connected to ground via lead 1ₘ₁, bond pad 5, electrically conductive connection v₂, bond pad 6 and lead 1ₘ₂. This connection corresponds to connection 1ₘ in FIG. 3.

Furthermore, according to FIG. 4, bond pad 1d of monolithic controller 1 is connected to external connection point A via lead 1ₐ₁, bond pad 9, electrically conductive connection v₃, electrically conductive connection v₅, electrically conductive connection v₄, bond pad 10 and lead 1ₐ₂. This connection corresponds to connection 1ₐ in FIG. 3.

An advantage of the example embodiment of the present invention is that the devices illustrated in the figures are able to be produced by one and the same production line. If a customer desires the production of controllers without high demands on pulse stability, EMC resistance and electrostatic response, then a device according to FIG. 4, which does not include any supplementary components, may be produced for this customer. For other customers who intend to use the controller in an environment where high demands are made on pulse stability, EMC resistance and electrostatic response, devices according to FIG. 2, which include supplementary components 2 and 3, may be produced by the same production line, supplementary components 2 and 3 being realized in the form of SMD components. Furthermore, using the same production line, it is also possible to produce controllers according to the related art whose cooling bodies are, for instance, solid blocks made of copper, which are not provided with individual conductor structures.

To save costs, the bond fitting may be optimized as an alternative to the exemplary embodiment shown in FIG. 4.

1-8. (canceled)

9. A monolithic controller for a generator unit of a motor vehicle, the monolithic controller being fixedly connected to a cooling body, wherein the cooling body is a thermally conductive substrate provided with electrically conductive connections, and the monolithic controller is fixedly connected to the substrate in unpackaged form.

10. The monolithic controller as recited in claim 9, wherein the monolithic controller is connected to the substrate via a rear side.

11. The monolithic controller as recited in claim 9, wherein the electrically conductive connections are one of copper structures or made of conductive paste printing.

12. The monolithic controller as recited in claim 9, wherein the monolithic controller includes bond pads on its front side for electrical contacting.

13. The monolithic controller as recited in claim 9, wherein the monolithic controller is electrically contacted by at least one supplemental component, the supplemental component being an SMD component, the SMD component being fixedly connected to the substrate.

14. The monolithic controller as recited in claim 13, wherein two SMD components are provided on the substrate and the two SMD components are in electrical contact with each other via an electrically conductive connection.

15. The monolithic controller as recited in claim 9, wherein a cross-sectional area of the substrate is larger than a cross-sectional area of the monolithic controller.

16. The monolithic controller as recited in claim 13, wherein the monolithic controller is electrically contacted by one of the SMD components via a bond pad provided on a front side, a lead that is not part of the substrate, and a bond pad provided on the substrate.
